(19) United States
(12) Patent Application Publication
(10) Pub. No.: US 2022/0128486 A1
(43) Pub. Date: Apr. 28, 2022

(54) MEASURING DEVICE FOR DETERMINING A DIELECTRIC CONSTANT

(71) Applicant: Endress+Hauser SE+Co. KG, Maulburg (DE)

(72) Inventor: Thomas Blödt, Steinen (DE)

(21) Appl. No.: 17/425,559

(22) PCT Filed: Dec. 10, 2019
(86) PCT No.: PCT/EP2019/084414

§ 371 Date: Jul. 23, 2021

(30) Foreign Application Priority Data
Jan. 29, 2019 (DE) 10 2019 102 142.1

(51) Int. Cl. G01N 22/00

(52) U.S. Cl. CPC G01N 22/00

(57) ABSTRACT

Disclosed is a measuring device and a method for measuring a dielectric value of a fill substance. The measuring device includes a signal production unit for driving a transmitting unit to transmit a radar signal toward the fill substance; a receiving unit for receiving of the radar signal; and an evaluation unit to ascertain an amplitude of the received signal, a phase shift, and/or a signal travel time of the radar signal. Based on the signal travel time, the phase shift, and/or the ascertained amplitude, the dielectric value can be determined. The transmitting unit and the receiving unit comprise at least two radiating elements arranged relative to one another in a corresponding number of rows. Because of a per row increasing phase delay, the measuring range over which the dielectric value can be determined is increased.

The invention relates to a measuring device for determining the dielectric value of a fill substance as well as to a method for operating the measuring device.

In automation technology, especially in process automation technology, field devices are often applied, which serve for registering and/or for influencing process variables. For registering process variables, sensors are applied, which are used, for example, in fill level measuring devices, limit level measuring devices, flow measuring devices, pressure- and temperature measuring devices, pH measuring devices, conductivity measuring devices, or dielectric value measuring devices. These register the corresponding process variables, fill level, limit level, flow, pressure, temperature, pH value, redox potential, conductivity, or dielectric value. In such case, “container” within the scope of the invention refers also to open containers, such as, for example, vats, lakes or oceans or flowing bodies of water. A large number of these field devices are produced and sold by the firm, Endress+Hauser.

The determination of dielectric value (also known as “dielectric constant”, “dielectric number” or “relative permittivity”) is of great interest both in the case of solid-, as well as also in the case of liquid fill substances, such as, for example, fuels, waste waters or chemicals, since this value can be a reliable indicator for impurities, moisture content or substance composition. In order to determine the dielectric value according to the state of the art, above all, in the case of liquid fill substances, the capacitive measuring principle can be used. In such case, the effect is utilized that the capacitance of a capacitor changes proportionally to the dielectric value of the medium located between the two electrodes of the capacitor.

Alternatively, it is also possible to co-determine the dielectric value of a (liquid) medium in a container interior virtually parasitically during its fill level measurement. This requires the measuring principle of guided radar, in the case of which microwaves are guided in the medium via an electrically conductive waveguide. Such combined fill level- and dielectric measuring is described in disclosure document DE 10 2015 117 205 A1.

An alternative to capacitive or microwave-based dielectric value measuring is inductive measuring. This measuring principle rests on the fact that the impedance of a coil depends not only on its number of turns, the winding material and the material of the coil core, but also on the fill substance, which borders the coil and, thus, is penetrated by the magnetic field of the coil. In this case, the dielectric value can be determined by measuring the complex coil impedance.

Based on the above mentioned measuring principles, in given cases, a very exact determining of the dielectric value is possible. However, the value range in which the dielectric is determinable, as a rule, decreases to a greater extent the more exactly the value is measurable. An object of the invention, therefore, is to provide a measuring device with which the dielectric value is determinable over an as large as possible value range.

The invention achieves this object by a measuring device for measuring a dielectric value of a fill substance, comprising:
a signal production unit, which is designed to drive
a transmitting unit in such a manner by means of an electrical, high frequency signal that the transmitting unit transmits a radar signal in the direction of the fill substance,
a receiving unit, which is so arrangeable in the container that it receives the radar signal as received signal after passage through the fill substance, and
an evaluation unit, which is designed, at least based on the received signal,
   to ascertain an amplitude of the received signal, a phase shift of the received signal relative to the high frequency signal and/or a signal travel time of the radar signal between the transmitting unit and the receiving unit, and
   to determine the dielectric value based on the ascertained signal travel time, the phase shift and/or the ascertained amplitude.

For increasing the measuring range, the measuring device of the invention is characterized in that the transmitting unit and/or the receiving unit comprise/comprises at least two radiating elements, which are arranged relative to one another in a corresponding number of rows. In such case, there is placed relative to the, in each case, other unit, thus, the transmitting- or receiving unit, before the radiators, a transmitting layer transmitting the radar signal.

The terminology, “unit”, in the context of invention, means, in principle, every electronic circuit, which is suitably designed for the contemplated application. It can thus, depending on requirements, be an analog circuit for producing, or processing, corresponding analog signals. It can also be a (semiconductor based) digital circuit, such as an FPGA or a storage medium in cooperation with a program. In such case, the program is designed to perform the corresponding method steps, or to apply the necessary calculational operations of the pertinent unit. In this context, different electronic units of the measuring device can in the sense of invention potentially also use a shared physical memory, or be operated by means of the same physical, digital circuit.

In the context of the invention, the term “radar” is defined generally as a signal, or electromagnetic wave, having a frequency between 0.03 GHz and 300 GHz. Regarding the measuring device of the invention, it is, however, advantageous that the signal production unit be designed to produce the high frequency signal with a frequency above 1 GHz.

The functioning of a “radiating element” in the context of invention is, on the one hand, the manner in which antennas work in general, thus to radiate the radar signal into the near field as well as also into the far field. Radiating elements include, however, also any elements, which radiate radar signals only into the near field. Due to the reciprocal properties of the transmitting and/or receiving, this property holds true analogously for the radiating as well as for the receiving of the radar signal.

According to the invention, the effect is utilized that an increasing-, or decreasing, phase delay can be set between the individual rows. This has a measuring range increasing effect, and is known analogously in audio technology as “dynamic range compression”, or in image processing as “tone mapping”.

On the one hand, it is possible to achieve an increasing phase delay per row, in that before-, or following, the at least one radiating element of each row at least one delay element is placed in such a manner that the high frequency signal is transmitted per row, in each case, with a defined, increasing phase delay, or that the received signal received by the at least one radiating element is with increasing row delayed, in each case, by a defined, increasing- or decreasing phase. A delay element can be implemented, for example, as described in DE102012106938 A1.

Alternatively, the phase of the radar signal can be delayed row dependently, in that the transmitting unit and the receiving unit are tilted in such a manner relative to one another that the at least one radiating element of each row has with increasing row number, in each case, an increasing- or decreasing separation from the at least one radiating element of the corresponding row of the other unit. This variant with tilted arrangement is not limited to the situation in which the two units (transmitting- and receiving unit) comprise a corresponding number of rows, in which, in each case, at least one radiating element is arranged.

Moreover, another opportunity for implementing the row dependent phase delay is that in which the transmitting layer has a thickness, which increases- or decreases per row, in each case, in a defined manner. Above all, when the per row increasing phase delay of the radar signal should be set by an increasing- or decreasing layer thickness of the transmitting layer, advantageously the transmitting layer is manufactured of a material, which has a relative dielectric number between 2 and 40, or a magnetic permeability between 0.5 and 10. Accordingly, applied materials can be, for example:
ceramics such as Al₂O₃,
(glass fiber reinforced) plastics, such as especially PE, PP, PTFE, or
metal glasses, such as, for example, described in US 20160113113 A1.

In the context of the invention, it is not prescribed how many radiating elements are arranged per row. To increase the aperture in the lateral direction and, thus, to increase the resolution of the dielectric value measuring, it is, however, advantageous that per row at least two, especially more than 5, radiating elements are arranged on the transmitting unit and the receiving unit. In the case of a plurality of radiating elements per row advantageously a conductive trace structure is provided on the transmitting unit and the receiving unit symmetrically contacting the radiating elements of a row in such a manner that the high frequency signal or the received signal of each radiating element of the row is of equal phase. In this way, it is prevented that the radiating elements of the same row bring about different phase delays.

Besides the number of radiating elements, it is, additionally, not prescribed how many rows the transmitting unit or the receiving unit contains. Since also with rising number of rows the aperture is increased, and resolution of the dielectric value measuring rises, it is also advantageous that the transmitting unit and/or the receiving unit comprise/comprises more than two, especially more than 5 rows of, in each case, at least one radiating element. For compact design of the transmitting unit and the receiving unit, it is generally advantageous that the radiating elements be constructed as planar radiators, especially as patch-, spiral-, dipole- or fractal antennas.

The method to be applied for determining the signal travel time of the radar signal (and, thus, for determining the real part of the dielectric value) is according to the invention not prescribed. Thus applied as measuring principle can be, for example, the pulse travel time method, the FMCW method (acronym for “Frequency Modulated Continuous Wave”) or a phase evaluation method, such as, for example, an interferometric method. The measuring principles of the FMCW- and pulse radar-based travel time measuring methods are described, for example, in “Radar Level Measurement”; Peter Devine, 2000.

When the measuring device is to determine the signal travel time by means of the FMCW method, then the signal production unit is constructed to produce the high frequency signal with a varying frequency in such a manner that the evaluation unit can determine the signal travel time based on a frequency difference between the transmitted radar signal and the received radar signal. In the case of implementing the pulse travel time method, the signal production unit is constructed to produce the high frequency signal with pulse shape in such a manner that the evaluation unit can determine the signal travel time based on a pulse travel time between the transmitting unit and the receiving unit. Independently of the measuring principle for determining the travel time, the signal production unit is advantageously designed to produce the high frequency signal with a frequency of at least 1 GHz. The higher the frequency, the more compact the measuring device, as a whole, can be designed. Moreover, in the case of higher frequencies also the dielectric value of fill substances with higher electrical conductivity can be determined, such as, for example, salt-containing liquids, without causing short circuiting between the transmitting unit and the receiving unit.

Analogously to the measuring device of the invention, the object of the invention is additionally achieved by a corresponding measuring method, by means of which a dielectric value of a fill substance located in a container can be determined. Corresponding to the measuring device, the measuring method includes method steps as follows:
transmitting a radar signal in the direction of the fill substance,
receiving the radar signal after passage through the fill substance,
determining an amplitude of the received radar signal, a phase shift between transmitting and receiving the radar signal and/or a signal travel time between transmitting and receiving the radar signal, and
ascertaining the dielectric value based on the amplitude, the phase shift and/or the signal travel time.

The method is distinguished analogously to the measuring device of the invention by the fact that the radar signal is transmitted and/or received in such a manner via radiating elements arranged relative to one another in at least two rows that the received signal received by the at least one radiating element per row is delayed with increasing row number by, in each case, a defined, increasing- or decreasing phase.

The invention will now be explained in greater detail based on the appended drawing, the figures of which show as follows:

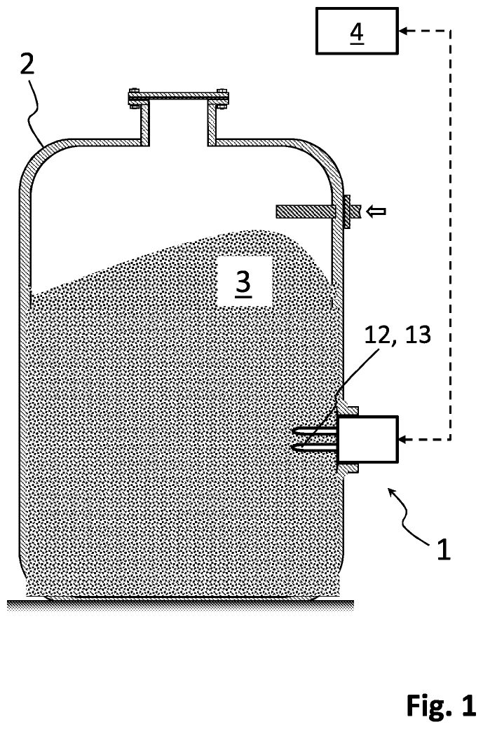

FIG. 1 a schematic arrangement of a measuring device of the invention mounted on a container,

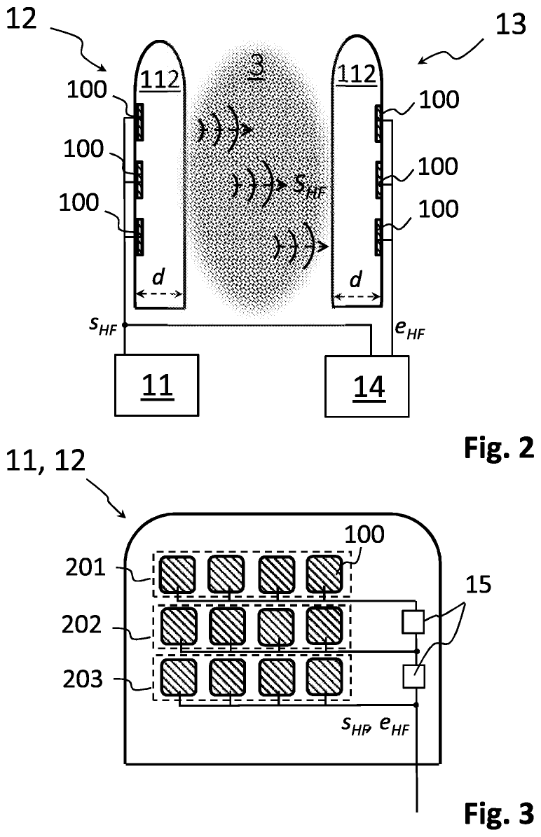

FIG. 2 a construction, in principle, of the measuring device of the invention,

FIG. 3 a front view of the transmitting unit, or the receiving unit, and

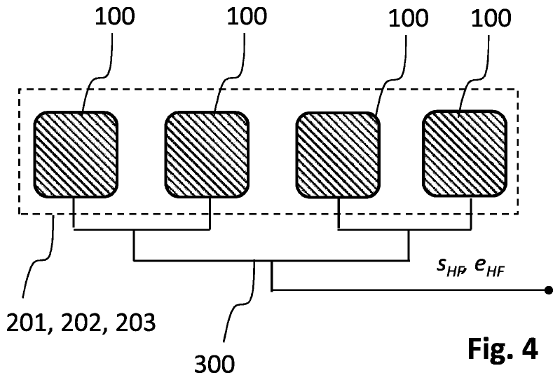

FIG. 4 a possible symmetric driving of the radiating elements in a row of the transmitting unit or the receiving unit.

For providing a general understanding of the measuring device 1 of the invention, FIG. 1 shows a schematic arrangement of the measuring device 1 mounted on a closed container 2. The invention can also be applied on open containers such as pipes. In the container 2 shown in FIG. 2, a fill substance 3 is located, whose dielectric value DK is to be determined. For this, the measuring device 1 is arranged laterally at a port of the container 2, such as, for example, a flanged port. In such case, the measuring device 1 is so designed that a transmitting unit 12 and a receiving unit 13 of the measuring device 1 extend out from the inner wall of the container 2 into the container interior and, as a result, are in contact with the fill substance 3. The units 12, 13 are parallel in the illustrated form of embodiment, thus oriented without any skew relative to one another. In such case, the fill substance 3 is located, at least partially, between the two units 12, 13.

The fill substance 3 can be liquid such as drinks, paint, or fuel, such as liquified gases or mineral oils. Another option is, however, also the application of the measuring device 1 in the case of bulk good formed fill substances 3, such as, for example, cement, food, or feed, grains or flour. Depending on type of fill substance 3, very different dielectric values DK can be involved. Accordingly, the measuring device 1 must be designed to be able to determine the dielectric value DK over a very broad measuring range.

The measuring device 1 can be connected to a superordinated unit 4, for example, a process control system. Implemented as interface can be, for instance, a “PROFIBUS”, “HART” or “wireless HART” interface. The dielectric value DK can be transmitted in this way. Also other information with reference to the general operating condition of the measuring device 1 can be communicated.

The circuit construction, in principle, of the measuring device 1 is illustrated in FIG. 2 in greater detail. As can be seen, the transmitting unit 12 serves for transmitting a radar signal S_{HF}. The parallel, oppositely arranged receiving unit 13 serves for receiving the radar signal S_{HF}, after it has penetrated the fill substance 3 between the two units 12, 13.

For producing the radar signal S_{HF}, a signal production unit 11 drives the transmitting unit 12 by means of a corresponding high frequency signal s_{HF}. In such case, the wavelength of the radar signal S_{HF} is established by the frequency of the high frequency signal s_{HF}. Since the dielectric value DK of the fill substance 3 is ascertained according to the invention by measuring the amplitude of the received radar signal S_{HF} or by measuring the signal travel time between the transmitting unit 12 and the receiving unit 13, the receiving unit 13 is connected to an appropriately designed evaluation unit 14. In this way, the evaluation unit 14 receives the radar signal S_{HF} arriving at the receiving unit 13 correspondingly as an electrical, received signal e_{HF}. Since the amplitude behaves proportionally to the imaginary part of the dielectric value DK, the imaginary part can be determined based on the amplitude of the received radar signal S_{HF}. Analogously, the real part of the dielectric value DK can be determined based on the signal travel time, or the phase shift.

Since according to the invention it is not prescribed which measuring principle should be applied for determining the signal travel time of the radar signal S_{HF}, the evaluation unit 14 and the signal production unit 11 are constructed as a function of the implemented measuring principle. Known circuit components can be applied in each case. Thus, in the case of FMCW, the signal production unit 11 can use a PLL (“phase locked loop”); and the evaluation unit 14 can mix the transmitted high frequency signal s_{HF} with the received signal e_{HF} by means of a mixer, in order to ascertain the travel time based on the frequency difference between the mixed signals. Such can occur, for example, per FFT (“Fast Fourier Transformation”) of the mixed signal e_{HF} by means of a corresponding computing block.

In the case of implementing the pulse travel time method, the signal production unit 11 can comprise a correspondingly cyclically driven oscillator, for example, a voltage controlled oscillator or just a quartz oscillator, for pulse shaped production of the high frequency signal s_{HF}. The evaluation unit 14 can process the received signal e_{HF} in the case of the pulse travel time method by undersampling. Thus, the evaluation unit 14 can ascertain the signal travel time of the corresponding signal maximum based on the sampled and, thus, time stretched signal. Travel time determination can be performed alternatively to the pulse travel time method or the FMCW method using any other suitable method for determining the signal travel time. Another possible method of travel time determination is described, for example, in WO 2017045788 A1.

Regarding structure, the transmitting unit 12 and the receiving unit 13 can, in principle, be designed analogously. An essential feature of the invention, in such case, is that the transmitting unit 12 and/or the receiving unit 13 do not have just one radiating element 100, but, instead, at least two radiating elements 100, which are arranged in row form relative to one another. In the embodiment shown in FIG. 2, the two units 12, 13 have three rows 201, 202, 203, in which the radiating elements 100 are arranged (compare also FIG. 3). Placed in front of the radiating elements 100 in each unit 12, 13 for protection against fill substance 3 is, in each case, a transmitting layer 112, which allows the radar signal S_{HF} to pass through it. Suitable layer materials are, for example, Al₂O₃, PE, PP, PTFE or metal glasses.

According to the invention, the radiating elements 100 of the individual rows 201, 202, 203 are so driven by the transmitting unit 12, or the receiving unit 13, that the received signal e_{HF} received by the radiating elements 100 is delayed with increasing row number 201, 202, 203 in each case by a defined, increasing- or decreasing phase. Such can, in principle, be implemented in two ways. On the one hand, the radar signal S_{HF} can be transmitted in the transmitting unit 12 already with per row increasing phase delay. Alternatively or supplementally, the per row increasing phase delay can also be introduced at the receiving unit 13. Because of the per row 201, 202, 203 increasing phase delay, the measuring range, over which the dielectric value DK can be determined, is increased.

Both in the case of transmitting unit 12 as well as also in the case of the receiving unit 13, a corresponding implementing of the per row 201, 202, 203 increasing phase delay is, in turn, possible in different ways. For example, the transmitting layer 112 can have a layer thickness d increasing- or decreasing per row 201, 202, 203, such that a wedge- or step shaped cross section of layer 112 results. In this way, each row 201, 202, 203 has a differently long “virtually optical” signal travel distance of the radar signal S_{HF}, whereby a corresponding phase delay is set between the rows 201, 202, 203 of the units 12, 13. Since a higher dielectric number of the layer 112 produces a greater “refraction” of the radar signal S_{HF}, the layer 112 advantageously has a relative dielectric number between 2 and 40, or a magnetic permeability between 0.5 and 10.

Instead of increasing layer thickness d of the transmitting layer 112, the same effect can be achieved by tilting the transmitting unit 12 and the receiving unit 13 appropriately relative to one another. Since the layer thickness d in the case of the embodiment shown in FIG. 2 is constant over the rows 201, 202, 203 and no tilting is provided (the transmitting unit 12 and the receiving unit 13 are oriented parallel relative to one another), the phase delay increasing per row number 201, 202, 203 is set by an appropriate driving of the individual rows 201, 202, 203 by the signal-production unit 11, or by the evaluation unit 14. For this, the rows 201, 202, 203 can, such as shown in FIG. 3, depending on the phase delay to be set, have corresponding delay elements 15 placed in front of them (or, in the case of the receiving unit 13, following them).

The serial arrangement of the two delay elements 15 shown in FIG. 3 effects relative to the three rows 201, 202, 203 that the antennas 100 of the physically lowest row 203 are not delayed, while the physically uppermost row 201 experiences a doubled phase delay compared with second row 202 (assuming that the two delay elements 15 produce the same phase delay). Per row 201, 202, 203, thus the phase delay decreases, in each case, by the value of a delay element 15. For the purpose of individual adjusting of the phase delay, the phase delay elements 15 can naturally also be so designed that they do not bring about the same phase delay.

Due to the high frequency of the radar signal in the GHz range, it is preferred for the purpose of compact design that the radiating elements 100 be designed as planar radiators. For example, the radiating elements 100 can be designed as patch-, spiral- or fractal antennas, which are arranged on a circuit board substrate. Thus, the radiating elements 100 can be applied, or structured, analogously to conductive traces, for example, as copper layers. In the case of a frequency between 2 GHz and 30 GHz, the edge length of the patch antennas lies between 0.2 mm and 50 mm. When no far field should be enabled, the edge length can be significantly less than a fourth of the wavelength of the radar signal S_{HF}. A radiating only in the near field has the advantage that the radar signal S_{HF} can be radiated with higher transmitting power, without violating governmental radio regulations.

When the radiating elements 100 of the transmitting unit 12 and the receiving unit 13 are placed on one or more circuit board substrates, the radiating elements 100 can be designed as corresponding conductive traces, especially as microstrip lines, with which signal production unit 11 and the evaluation unit 14 are contacted.

In order that the radiating elements 100 of the rows 201, 202, 203 do not (to the extent that a row has more than one radiating element 100) relative to one another bring about a deviating phase relative to the radar signal S_{HF}, the path length of each conductive trace of the radiating elements 100 of each row 201, 202, 203 is made equally long. A possible variant for implementing this in the case of an even number of radiating elements 100 per row 201, 202, 203 is shown in FIG. 4. There, the four radiating elements 100 of a row 201, 202, 203 are combined to one potential via a tree shaped conductive trace structure 300. In such case, the conductive trace structure 300 has two sections of branching, wherein in each section, in each case, two equally long trace branches branch to the radiating elements 100. In this way, the radiating elements 100 of the rows 201, 202, 203 are symmetrically contacted, so that the high frequency signal s_{HF}, or the received signal e_{HF}, of each radiating element 100 of each row 201, 202, 203 is equal phase.

### LIST OF REFERENCE CHARACTERS

1 measuring device
2 container
3 fill substance
4 superordinated unit
11 signal production unit
12 transmitting unit
13 receiving unit
14 evaluation unit
15 delay element
100 radiating elements
112 transmitting layer
201-203 rows
300 conductive trace structure
DK dielectric value
d thickness of the transmitting layer
e_{HF} received signal
S_{HF} radar signal
s_{HF} high frequency signal

1-13. (canceled)

14. A measuring device for measuring a dielectric value of a fill substance in a container, comprising:
a signal production unit, which is designed to drive a transmitting unit in such a manner by means of an electrical, high frequency signal that the transmitting unit transmits a radar signal in a direction of the fill substance;
a receiving unit, which is so arrangeable in the container that it receives the radar signal as received signal after passage through the fill substance; and
an evaluation unit, which is designed, at least based on the received signal, to ascertain an amplitude of the received signal, a phase shift of the received signal relative to the high frequency signal and/or a signal travel time of the radar signal between the transmitting unit and the receiving unit and to determine the dielectric value based on the ascertained signal travel time, the phase shift and/or the ascertained amplitude,
wherein the transmitting unit and/or the receiving unit include at least two radiating elements arranged in a corresponding number of rows relative to one another, and
wherein there is placed relative to the, in each case, other unit, thus, the transmitting- or receiving unit, before the radiators, a transmitting layer transmitting the radar signal.

15. The measuring device as claimed in claim 14, wherein before, or following, the at least one radiating element of each row at least one delay element is placed in such a manner that the high frequency signal is transmitted per row, in each case, with a defined, increasing phase delay, or the received signal received by the at least one radiating element is with increasing row number delayed, in each case, by a defined, increasing or decreasing phase.

16. The measuring device as claimed in claim 14, wherein the transmitting unit and the receiving unit are tilted in such a manner relative to one another that the at least one radiating element of each row has with increasing row number, in each case, an increasing or decreasing separation from the at least one radiating element of the corresponding row of the other unit when the two units comprise a corresponding number of rows, in which, in each case, at least one radiating element is arranged.

17. The measuring device as claimed in claim 14, wherein the transmitting layer has a thickness that increases or decreases per row, in each case, in a defined manner.

18. The measuring device as claimed in claim 14, wherein at least two radiating elements are arranged per row.

19. The measuring device as claimed in claim 18, wherein a conductive trace structure is provided on the transmitting unit or the receiving unit symmetrically contacting the radiating elements of a row in such a manner that the high frequency signal or the received signal of each radiating element of the row is of equal phase.

20. The measuring device as claimed in claim 14, wherein the transmitting unit and/or the receiving unit include more than two rows with, in each case, at least one radiating element.

21. The measuring device as claimed in claim 14, wherein the transmitting layer is manufactured of a material which has a relative dielectric number between 2 and 40, and/or a magnetic permeability between 0.5 and 10.

22. The measuring device as claimed in claim 14, wherein the signal production unit is constructed to produce the high frequency signal with a varying frequency in such a manner that the signal travel time is determinable by means of the evaluation unit based on a frequency difference between the transmitted radar signal and the received radar signal.

23. The measuring device as claimed in claim 14, wherein the signal production unit is designed to transmit the high frequency signal in such a manner with pulse shape that the signal travel time is determinable by means of the evaluation unit based on a pulse travel time between the transmitting unit and the receiving unit.

24. The measuring device as claimed in claim 14, wherein the signal production unit is designed to produce the high frequency signal with a frequency of at least 1 GHz.

25. The measuring device as claimed in claim 14, wherein the radiating elements are constructed as planar radiators, including patch, spiral, or fractal antennas.

26. A method for measuring a dielectric value of a fill substance in a container comprising:
providing a measuring device for measuring the dielectric value of the fill substance, including:
a signal production unit, which is designed to drive a transmitting unit in such a manner by means of an electrical, high frequency signal that the transmitting unit transmits a radar signal in the direction of the fill substance;
a receiving unit, which is so arrangeable in the container that it receives the radar signal as received signal after passage through the fill substance; and
an evaluation unit, which is designed, at least based on the received signal, to ascertain an amplitude of the received signal, a phase shift of the received signal relative to the high frequency signal and/or a signal travel time of the radar signal between the transmitting unit and the receiving unit and to determine the dielectric value based on the ascertained signal travel time, the phase shift and/or the ascertained amplitude,
wherein the transmitting unit and/or the receiving unit include at least two radiating elements arranged in a corresponding number of rows relative to one another, and
wherein there is placed relative to the, in each case, other unit, thus, the transmitting- or receiving unit, before the radiators, a transmitting layer transmitting the radar signal;
transmitting a radar signal in the direction of the fill substance;
receiving the radar signal after passage through the fill substance;
determining an amplitude of the received radar signal, a phase shift between transmitting and receiving the radar signal and/or a signal travel time between transmitting and receiving the radar signal; and
ascertaining the dielectric value based on the amplitude, the phase shift and/or the signal travel time,
wherein the radar signal is transmitted and/or received in such a manner via the radiating elements arranged relative to one another in at least two rows that the received signal received by the at least one radiating element per row is delayed with increasing row number by, in each case, a defined, increasing- or decreasing phase.
